(19) United States
(12) Patent Application Publication
(10) Pub. No.: US 2020/0176248 A1
(43) Pub. Date: Jun. 4, 2020

(54) SURFACE CONTAMINANT REDUCTION IN CONTROLLED ENVIRONMENTS

(71) Applicants: Zyvex Labs, LLC, Richardson, TX (US); The Board of Trustees of the University of Illinois, Urbana, IL (US)

(72) Inventors: JAMES OWEN, GARLAND, TX (US); JOSHUA BRENDAN BALLARD, BLOOMINGTON, IN (US); JOSEPH W. LYDING, CHAMPAIGN, IL (US); JOHN RANDALL, RICHARDSON, TX (US)

(21) Appl. No.: 16/691,347

(22) Filed: Nov. 21, 2019

Related U.S. Application Data
(60) Provisional application No. 62/773,040, filed on Nov. 29, 2018.

(51) Int. Cl. H01L 21/02; H01L 21/027; C23C 16/04; C23C 16/44

(52) U.S. Cl. CPC H01L 21/02271; C23C 16/4401; C23C 16/042; H01L 21/027

(57) ABSTRACT

A method for reducing the amount of mobile surface molecules present on a substrate surface includes providing a substrate having an area of interest, where the substrate is disposed within a controlled environment (e.g., a UHV environment). In some embodiments, a mask is positioned in a first position over the area of interest. Thereafter, a first deposition of a reactive material from a reactive material source is performed onto a first substrate region. The mask, while in the first position, blocks deposition of the reactive material within the area of interest. The mask may then positioned in a second position over the area of interest. In some embodiments, a second deposition of the reactive material from the reactive material source is performed to circumscribe the area of interest with the reactive material. In various embodiments, mobile surface molecules are captured using the deposited reactive material.

### CROSS-REFERENCE TO RELATED APPLICATION

The present application claims priority to and the benefit of U.S. Provisional Patent Application No. 62/773,040, filed Nov. 29, 2018, which is hereby incorporated by reference in its entirety

### BACKGROUND

Vacuum systems have become a ubiquitous part of semiconductor and nanotechnology manufacturing and characterization processes, as well as a number of other research and industrial applications. Generally, a vacuum system or other controlled environment may be used to reduce the likelihood of unwanted reactions or contamination of substrates, objects, and/or materials that are placed within the vacuum system or controlled environment. In the case of vacuum systems, the intent is to reduce or eliminate the impingement of unwanted gas atoms and molecules onto the clean, and possibly reactive, surfaces of a substrate. There are various levels of vacuum systems including low vacuum (e.g., 25 Torr), medium vacuum (e.g., 25 Torr to 1 mTorr), high vacuum (e.g., 1 mTorr to 1×10⁻⁹ Torr), ultra-high vacuum (UHV) (e.g., 1×10⁻⁹ Torr to 1×10⁻¹² Torr), and extremely high vacuum (e.g., less than 1×10⁻¹² Torr).

For a number of relevant scientific and technological processes, it is desirable to operate in a vacuum system to keep substrate surfaces as clean as possible. For purposes of this discussion, it is noted that a Langmuir is a unit of gas exposure (or dosage) to a surface (e.g., a substrate surface), where 1 Langmuir is the amount of gas exposure required so that each surface atom is expected to have been impacted by one gas atom, and is defined as 10⁻⁶ Torr-second. Thus, even at high vacuum levels, such as at 1×10⁻⁶ Torr, roughly 1 billion times lower pressure than atmospheric pressure (i.e., approximately 760 Torr), there is still such an abundance of gas molecules present that it only takes one second for each surface atom to be impacted by a molecule from the gas phase. If the gas molecules have a high sticking coefficient on the substrate surface, then in roughly 1 second the entire substrate surface would be contaminated. By going to UHV conditions, for example 1×10⁻¹⁰ Torr, the length of time before all of the surface atoms are contacted by a molecule from the gas phase is extended to roughly 10,000 seconds or 2.78 hours. Fortunately, in most UHV systems the majority of the remaining gas molecules present are hydrogen (H₂), which are typically not very reactive. The timescale for contamination therefore depends on the partial pressures of reactive species, such as oxygen, water, CO, CO₂, and hydrocarbon molecules. If these species can have their partial pressures driven as low as possible, then surfaces can theoretically be kept clean for long periods of time. Different vacuum pumping technologies have different pumping speeds for different gasses and these can be utilized to drive down the partial pressures of the species that are typically most reactive to the substrate surface that is being protected.

However, there are situations where, even with all of these various vacuum technologies at play, surface contamination is still a problem and often the molecules involved find their way to the substrate surface in quantities that cannot be accounted for simply from gas-phase adsorption (e.g., because of the very low pressures in the UHV environment). Finding a reliable approach to mitigate such surface contamination has remained a critical challenge.

Accordingly, there remains a need for improved surface contaminant reduction in controlled environments.

### BRIEF DESCRIPTION OF THE DRAWINGS

FIG. 1 is a flow chart of a method for reducing the amount of mobile surface molecules present on a substrate surface, according to one or more aspects of the present disclosure;

FIG. 2 illustrates a plan view of a system including a substrate having an area of interest defined therein, according to some embodiments;

FIG. 3A illustrates a plan view, and FIG. 3B provides a cross-section view along a section A-A′ shown in FIG. 3A, of the system of FIG. 2 further including a mask positioned over the area of interest, in accordance with some embodiments;

FIG. 4A illustrates a plan view, and FIG. 4B provides a cross-section view along a section B-B′ shown in FIG. 4A, of the system of FIG. 2 including the mask positioned over the area of interest and after a first deposition of a reactive material, in accordance with some embodiments;

FIG. 5 illustrates a plan view of the system including the substrate, with the mask removed, and showing the result of the first deposition of the reactive material, according to some embodiments;

FIG. 6A illustrates a plan view, and FIG. 6B provides a cross-section view along a section C-C′ shown in FIG. 6A, of the system of FIG. 2 where the mask has been repositioned over the area of interest, in accordance with some embodiments;

FIG. 7A illustrates a plan view, and FIG. 7B provides a cross-section view along a section D-D′ shown in FIG. 7A, of the system of FIG. 2 including the mask repositioned over the area of interest and after a second deposition of the reactive material, in accordance with some embodiments;

FIG. 8 illustrates a plan view of the system including the substrate, with the mask removed, and showing the result of the second deposition of the reactive material, according to some embodiments;

FIGS. 9A and 9B illustrates scanning tunneling microscope (STM) images of a substrate on which a hydrogen depassivation lithography (HDL) process has been performed both before deposition of a reactive material (FIG. 9A) and after deposition of the reactive material (FIG. 9B), in accordance with some embodiments;

FIGS. 10A, 10B, 10C, and 10D illustrate X-ray photoelectron spectroscopy (XPS) spectra for carbon, oxygen, Ti, and molybdenum, respectively, before and after Ti deposition in UHV on a molybdenum disulfide (MoS₂) surface; according to some embodiments;

FIG. 11A provides a cross-section view along a section B-B′ shown in FIG. 4A, of the system of FIG. 2, with a reactive material source positioned at an alternate angle with respect to the substrate, in accordance with some embodiments;

FIG. 11B provides a cross-section view along a section B-B′ shown in FIG. 4A, of the system of FIG. 2, without the mask, and with the reactive material source positioned below the substrate, in accordance with some embodiments; and

FIG. 12 illustrates a semiconductor wafer including a plurality of die and scribe lines, where a reactive material is deposited in at least portions of the scribe lines, in accordance with some embodiments.

### DETAILED DESCRIPTION

Various embodiments are described hereinafter with reference to the figures, in which exemplary embodiments are shown. The claimed invention may, however, be embodied in different forms and should not be construed as being limited to the embodiments set forth herein. Like reference numerals refer to like elements throughout. Like elements will, thus, not be described in detail with respect to the description of each figure. It should also be noted that the figures are only intended to facilitate the description of the embodiments. They are not intended as an exhaustive description of the claimed invention or as a limitation on the scope of the claimed invention. In addition, an illustrated embodiment need not have all the aspects or advantages shown. An aspect or an advantage described in conjunction with a particular embodiment is not necessarily limited to that embodiment and can be practiced in any other embodiments even if not so illustrated, or if not so explicitly described. The features, functions, and advantages may be achieved independently in various embodiments or may be combined in yet other embodiments.

Before describing exemplary embodiments illustratively depicted in the several figures, a general introduction is provided to further understanding.

As discussed above, vacuum systems may be employed to reduce or eliminate the impingement of gas atoms and molecules onto surfaces of a substrate. To be most effective for keeping substrate surfaces as clean as possible, vacuum systems should be operated at as low of a pressure as possible. For this reason, ultra-high vacuum (UHV) systems have become an integral part of semiconductor (e.g., molecular beam epitaxy) and nanotechnology manufacturing and characterization processes. As previously noted, even at high vacuum levels (e.g., ˜1 billion times lower than atmospheric pressure), there is still such an abundance of gas molecules present that it only takes one second for each surface atom to be impacted by a molecule from the gas phase, and if the gas molecules have a high sticking coefficient on the substrate surface, then in roughly 1 second the entire substrate surface would be contaminated. By going to UHV conditions (e.g., 1×10⁻¹⁰ Torr), the length of time before all of the surface atoms are impacted by a molecule from the gas phase is extended to roughly 10,000 seconds or 2.78 hours. Further, if the partial pressures of reactive species, such as oxygen, water, CO, CO₂, and hydrocarbon molecules, can have their partial pressures driven as low as possible, then substrate surfaces can theoretically be kept clean for long periods of time, and a variety of vacuum pumping technologies may be utilized for this purpose.

However, even with all of these various vacuum technologies at play, surface contamination is still a significant problem and often the molecules involved find their way to the substrate surface in quantities that cannot be accounted for simply from gas-phase adsorption (e.g., because of the very low pressures in the UHV environment). In some embodiments, it is postulated that such contamination comes not from the gas phase, but from molecules on the surface of the substrate that have a high mobility on the surface (e.g., mobile surface molecules). However, finding a reliable approach to mitigate such mobile surface contamination has remained a critical challenge.

For purposes of this discussion, a mobile surface molecule is defined as a chemical species which is adsorbed to a surface (e.g., a substrate surface) and which has a low barrier to diffusion across the surface. Mobile surface molecules also have low volatility and therefore do not register in measurements of the partial pressures, for example, as measured by a mass spectrometer or residual gas analyzer in a vacuum system. The lack of volatility of mobile surface molecules has been demonstrated by the fact that heating to fairly high temperatures, for instance as in a standard vacuum system bake-out, does not seem to remove the mobile surface molecules. Generally, there has been little study of mobile surface molecules in UHV environments, and thus the types of molecules, their mobility on different surfaces, and other relevant features of these mobile surface species are not well known. There is some evidence that most of these molecules are hydrocarbons, but there may be other types as well, such as CO.

At least one example of the hydrocarbon nature of mobile surface molecules is found in the practice of the surface analytical technique X-ray photoelectron spectroscopy (XPS). XPS is a highly sensitive spectroscopic technique that measures the elemental composition of elements that exist near the surface of a given substrate material. Further, XPS can be used to identify fractions of a monolayer of elements and/or compounds on surfaces in a UHV environment. XPS spectra, obtained by irradiating a material with a beam of X-rays while simultaneously measuring the kinetic energy and number of electrons escaping from the material being analyzed, typically include a ubiquitous carbon peak, even when there is no obvious source of carbon. It has thus far been standard to simply ignore this ubiquitous carbon peak in the analysis of the XPS spectra. As another example of the hydrocarbon nature of mobile surface molecules, contamination on graphene surfaces have been reported (See e.g., J. Swett et al., “The Challenge of Contamination in Atomically Precise Manipulation of Graphene and 2D Materials,” MRS Spring Meeting, 2018), where such contamination has been attributed to mobile hydrocarbon molecules on the graphene surface. These mobile hydrocarbon molecules were reported as having low volatility and were therefore difficult to remove.

Further evidence of the presence of mobile surface molecules on surfaces in a UHV environment has been observed in hydrogen depassivation lithography (HDL) processes. In an HDL process, a scanning tunneling microscope (STM) is used to perform a lithography process via electron induced desorption of H atoms from a Si (100) 2X1 H-passivated surface. Even at a very low base pressure (e.g. 1×10¹⁰ Torr), there have been documented cases where an area of clean Si (i.e., where two or more H atoms have been removed by the HDL process) is filled with at least a monolayer of some contaminating molecule within minutes. If this contamination was coming from the gas phase it would take hours, not minutes, for the clean Si to have collected a monolayer coverage of the contaminating molecule(s). It is also common for large blobs of a particular contaminant, and which may be of unknown origin, to coalesce within the depassivated area (e.g., clean Si area). It has been generally assumed that such contaminant globules are mobile surface molecules which have been decomposed by the electron beam emanating from the STM tip, such that they are no longer mobile or simply find their way to the depassivated area and stick to the reactive Si surface where the H has been removed.

The mobile surface contamination problem is not only a problem for surfaces on which mobile surface molecules have a high mobility. For example, if an area of interest of a substrate (e.g., a portion of a substrate surface targeted for reduction in the amount of mobile surface molecules present) is in contact with another material surface (e.g., along an interface or at other regions of contact) on which mobile surface molecules have a high mobility, then there is a source of mobile surface molecules at the interface or at the other regions of contact. As such, contamination by mobile surface molecules can start at the interface or at the other regions of contact, and if the mobile surface molecules stick to the area of interest they may provide a passivated surface that allows the mobile surface molecules a growth path for propagation. Thus, the mobile surface contamination may still spread.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods for reducing the amount of mobile surface molecules present on surfaces in UHV systems or within other controlled environments. In some embodiments, a highly reactive material may be deposited in-situ onto a substrate. In some cases, a monolayer of the highly reactive material is deposited onto the substrate. However, in various examples, additional monolayers of the reactive material may be deposited for ease of processing and/or for reliability of the deposited material. In some embodiments, the reactive material may include titanium (Ti) or another reactive material. As used herein, the term “in-situ” is used to describe processes that are performed while a substrate, object, or material remains within a vacuum chamber of a processing system. In various examples, the vacuum chamber may include a UHV vacuum chamber, for example, so that the reactive material will not be rendered unreactive in a very short period of time. As noted above, and in some embodiments, the substrate may include an area of interest defining a region (e.g., a portion of a substrate surface) targeted for reduction in the amount of mobile surface molecules present, and in various examples the area of interest may include a device, circuit, material, metrology pattern, or generally any substrate region or feature in accordance with various user, design, technology, or metrology requirements. Moreover, in some examples, the area of interest may include an entire substrate surface (e.g., an entire front surface of the substrate). In various embodiments, the reactive material deposited in-situ may be deposited on a portion of the substrate surface outside, but in some cases adjacent to, the area of interest. That is, the area of interest may remain protected or free from the reactive material so as not to interfere with the device, circuit, material, metrology pattern, or other feature within the area of interest. By depositing the reactive material on a substrate surface, in accordance to the embodiments described herein, mobile surface molecules may be captured by the reactive material and thereby prevented from contaminating the area of interest. Thus, some embodiments of the present disclosure provide a reliable method for reducing the amount of mobile surface molecules present on a substrate surface (e.g., in a UHV environment) to protect areas of interest from contamination by the mobile surface molecules. Those skilled in the art will recognize other benefits and advantages of the methods and structures as described herein, and the embodiments described are not meant to be limiting beyond what is specifically recited in the claims that follow.

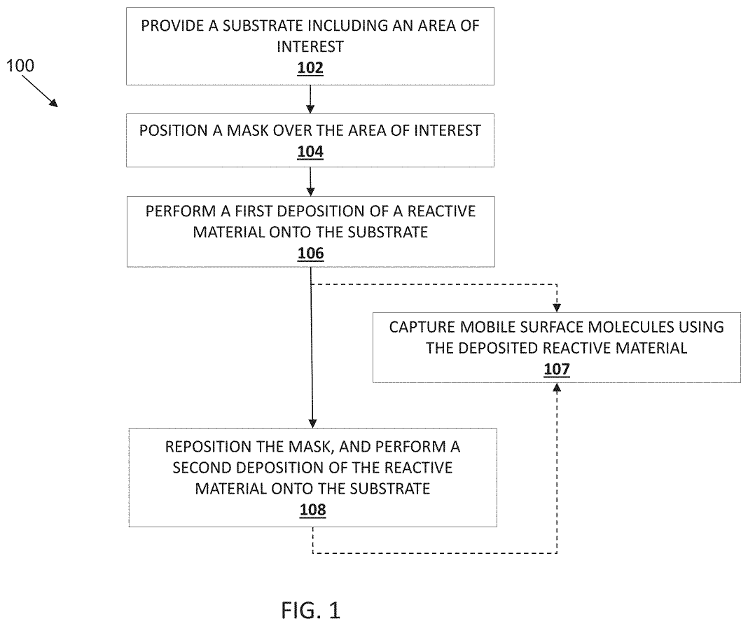

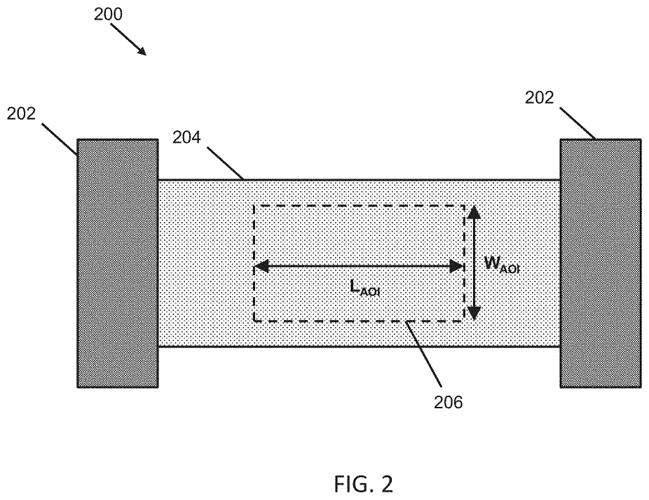

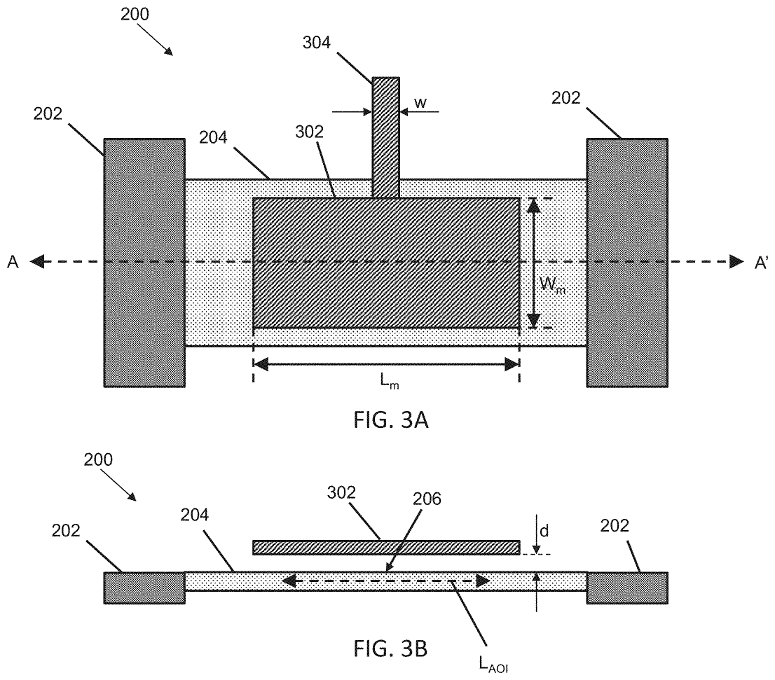

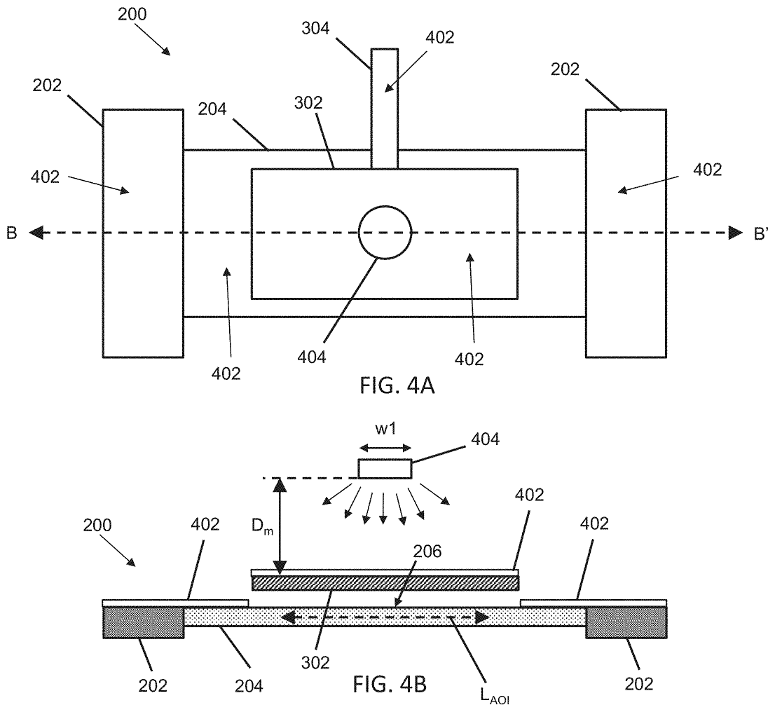

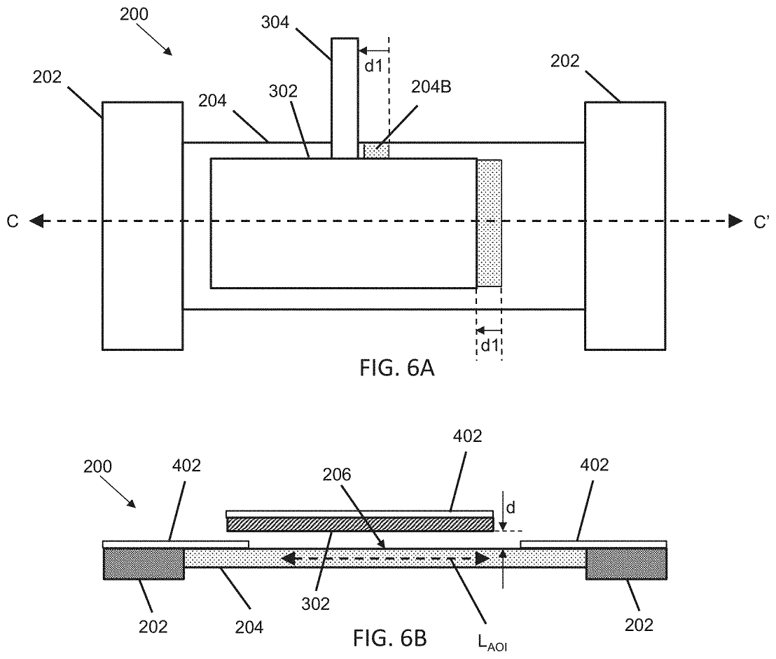

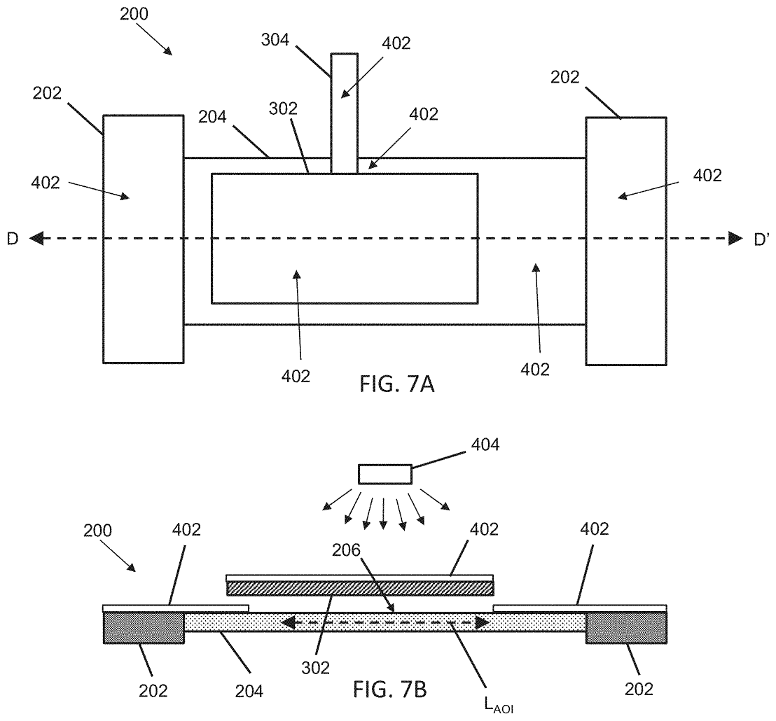

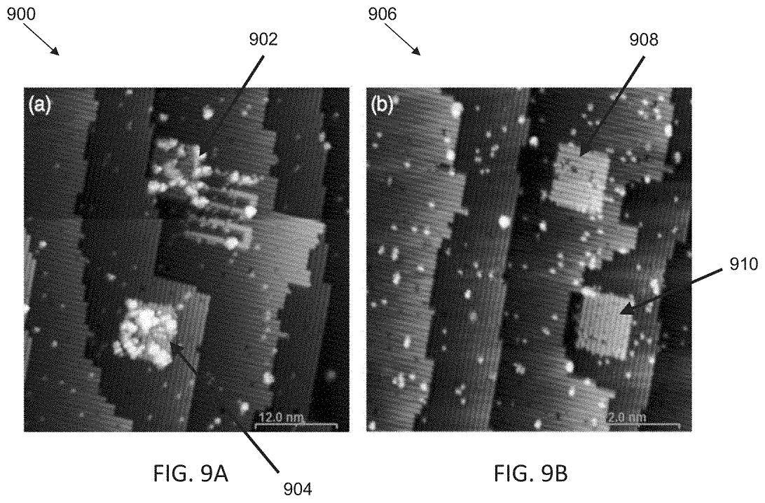

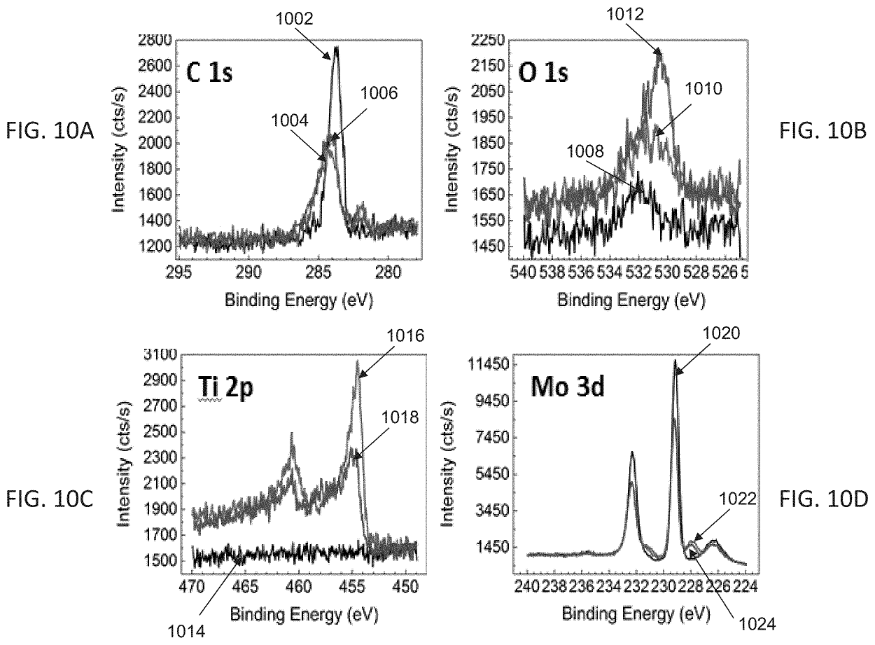

Referring now to FIG. 1, illustrated is a method 100 for reducing the amount of mobile surface molecules present on a substrate surface. The method 100 provides a general, exemplary method for carrying out one or more aspects of the present disclosure. In addition, FIGS. 2, 3A, 4A, 5, 6A, 7A, and 8 provide plan views, FIG. 3B provides a cross-section view along a section A-A′ shown in FIG. 3A, FIG. 4B provides a cross-section view along a section B-B′ shown in FIG. 4A, FIG. 6B provides a cross-section view along a section C-C′ shown in FIG. 6A, and FIG. 7B provides a cross-section view along a section D-D′ shown in FIG. 7A of a system 200 that may be used to implement one or more steps of the method 100. Moreover, it will be understood that additional process steps may be implemented before, during, and after the method 100, and some process steps described may be replaced or eliminated in accordance with various embodiments of the method 100. Other exemplary embodiments are described below in more detail with respect to FIGS. 9A, 9B, and 10A-10D.

The method 100 begins at block 102 where a substrate including an area of interest is provided in a vacuum or other controlled environment. Referring to the example of FIG. 2, in an embodiment of block 102, illustrated is the system 200 including a substrate 204 having an area of interest 206 having dimensions ‘L_{AOI} ’ and ‘W_{AOI} ’ defined on a front surface of the substrate 204. In some embodiments, the substrate 204 may be held in place by one or more clamps 202. Alternatively, or in addition, the substrate 204 may be disposed on or attached to a stage or other appropriate sample holder. In various examples, the system 200 is disposed within a vacuum chamber of a UHV system, as described above. In some embodiments, the substrate 204 may be a semiconductor substrate such as a silicon substrate. The substrate 204 may include various layers, including conductive or insulating layers formed on the substrate 204. In some cases, the substrate 204 may include various doping configurations depending on design requirements as is known in the art. The substrate 204 may also include other semiconductor materials such as germanium, silicon carbide (SiC), silicon germanium (SiGe), or diamond. Alternatively, the substrate 204 may include a compound semiconductor, an alloy semiconductor, or other substrate of interest. Further, in some embodiments, the substrate 204 may include an epitaxial layer (epi-layer), the substrate 204 may be strained for performance enhancement, the substrate 204 may include a silicon-on-insulator (SOI) structure, and/or the substrate 204 may have other suitable enhancement features. In addition, and as previously noted, the area of interest 206 on the substrate 204 may include a device and/or circuit, material, metrology pattern, or any other feature or substrate portion within which a reduction of mobile surface molecules is desired.

The method 100 proceeds to block 104 where a mask is positioned over the area of interest. Referring to the example of FIGS. 2, 3A, and 3B, in an embodiment of block 104, a mask 302 (e.g., such as a shadow mask) is positioned over the area of interest 206 to protect the area of interest 206 from a subsequent deposition of a reactive material (e.g., such as Ti). As shown in FIG. 3A, the mask 302 may be held in position by a support bar 304, having a width ‘w’, coupled to another portion of the system. In various embodiments, the mask 302 and support bar 304, for example by way of one or more actuators coupled to the support bar 304, may be moved as desired within a 3-dimensional coordinate system. As shown in the example of FIG. 3B, the mask 302 may be positioned a distance ‘d’ away from a surface of the substrate 204, such that the mask 302 is close to, but not in contact with, the substrate 204. In some embodiments, the distance ‘d’ may be equal to about 1 mm. Generally, the distance ‘d’ may be much smaller than a lateral dimension ‘Lₘ’ or ‘Wₘ’ of the mask 302, and much smaller than a distance ‘Dm’ between the mask 302 and a reactive material source 404 (FIG. 4B). It is also noted that to provide adequate protection to the area of interest 206, Lₘ may generally be greater than L_{AOI}, and Wₘ may generally be greater than W_{AOI}.

The method 100 then proceeds to block 106 where a first deposition of a reactive material onto the substrate is performed. Referring to the example of FIGS. 3A, 3B, 4A, and 4B, in an embodiment of block 106, a reactive material 402 is deposited. In some embodiments, the reactive material 402 includes Ti. However, other reactive materials such as barium, molybdenum, aluminum, magnesium, calcium, strontium, silicon, or alloys thereof, may be used instead of, or in conjunction with, Ti. For purposes of this disclosure, a reactive material may generally be described as a material which traps mobile surface molecules and/or gas molecules. The reactive material itself should not have a high surface mobility on the substrate 204, nor should it be volatile so as to decrease the vacuum level (raise the pressure) or provide additional molecules to the vapor phase that then would deposit on the area of interest. In various examples, the reactive material 402 may be deposited from a reactive material source 404, having an effective width ‘w1’, that is positioned normal to a surface of the substrate 204 and above the substrate 204 and the mask 302, such that all exposed surfaces of the substrate 204, the mask 302, the support bar 304, and the clamps 202 are coated with a layer of deposited reactive material 402. As shown in FIG. 4B, the area of interest 206, which is protected by the mask 302 during the deposition of the reactive material 402, remains free of the reactive material 402. In various examples, the reactive material source 404 may include a sublimation source, such as a Ti sublimation source. As such, in some embodiments, the reactive material source 404 may include a Ti filament (e.g., which may include a Ti wire or rod) through which a high current (e.g., ˜40 Amps) is passed and which causes the Ti filament to reach the sublimation temperature of Ti, such that all exposed surfaces of the substrate 204, the mask 302, the support bar 304, and the clamps 202 become coated with a layer of Ti. In some cases, all exposed surfaces of the substrate 204, the mask 302, the support bar 304, and the clamps 202 become coated with a monolayer of Ti. In various examples, additional monolayers of Ti may be deposited for ease of processing and/or for reliability of the deposited Ti layer. In other embodiments, the reactive material source 404 may deposit the reactive material 402 by another technique such as by physical vapor deposition (PVD), electron beam (e-beam) evaporation, and/or other suitable process.

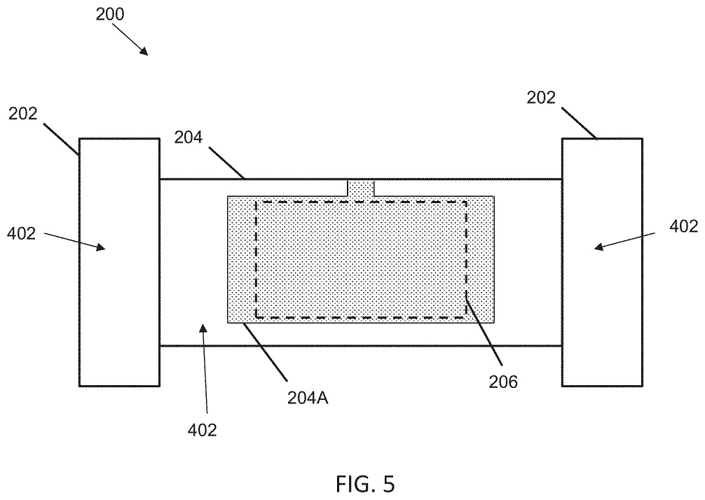

With reference to FIG. 5, illustrated therein is the substrate 204 and the clamps 202, after the first deposition of the reactive material 402 (block 106), and with the mask 302 removed. As shown, the mask 302 has been used to effectively protect the area of interest 206 by blocking the deposition of the reactive material 402 (e.g., Ti) within the area of interest. As such, a substrate region 204A, that is free of the reactive material 402, is defined around and including the area of interest 206. At this stage in the method 100, and as shown at block 107, the deposited reactive material 402 may already capture mobile surface molecules, for example, by a reaction between the reactive material 402 and impinging mobile surface molecules that effectively traps the mobile surface molecules. As such, after the first deposition of the reactive material 402 (block 106), the reactive material 402 will already provide a significant barrier to mobile surface molecules so that they do not reach the area of interest 206. Thus, in some embodiments, additional reactive material 402 need not be deposited, and the device, circuit, material, metrology pattern, or other feature within the area of interest 206 may proceed to be used for its intended purpose.

However, in some cases, it may be desirable to fully circumscribe the area of interest 206 with the reactive material 402 and thus provide additional protection from the mobile surface molecules. Therefore, in some embodiments, the method 100 may proceed to block 108 where the mask is repositioned, and where a second deposition of a reactive material onto the substrate is performed. Referring to the example of FIGS. 6A, 6B, 7A, and 7B, in an embodiment of block 108, the mask 302 is repositioned over the area of interest 206 to protect the area of interest 206 from a subsequent second deposition of a reactive material (e.g., such as Ti). In particular, as shown in the example of FIG. 6A, the mask 302 and the support bar 304 have been moved a distance as compared to the position of the mask 302 and the support bar 304 during the first deposition process (e.g., see FIGS. 3A, 3B, 4A, 4B), where the distance ‘d1’ is greater than the width ‘w’ of the support bar 304 (e.g., see FIG. 3A). Thus, repositioning the mask 302 and the support bar 304 exposes a substrate portion 204B that was protected by the support bar 304 during the first deposition. Nevertheless, in various embodiments and as illustrated in FIG. 6B, the mask 302 remains positioned over the area of interest 206, even after moving the mask 302 and the support bar 304 the distance ‘d1’. Thus, the area of interest 206 remains protected. Additionally, in the present example, the mask used during the second deposition process (block 108) is assumed to be the same as the mask used during the first deposition process (block 106). However, in some embodiments, a different mask may be used for each of the first and second deposition processes. Once again, and as shown in the example of FIG. 6B, the mask 302 may be positioned a distance ‘d’ away from a surface of the substrate 204, such that the mask 302 is close to, but not in contact with, the substrate 204.

Still referring to the example of FIGS. 6A, 6B, 7A, and 7B, in a further embodiment of block 108, the reactive material 402 is once again deposited. In some embodiments, the reactive material 402 deposited during the second deposition process (block 108) also includes Ti or another reactive material that was used during the first deposition process (block 106). The reactive material 402 may again be deposited using the reactive material source 404, as described above, such that all exposed surfaces of the substrate 204 (including the previously protected substrate portion 204B), the mask 302, the support bar 304, and the clamps 202 are coated with a layer of deposited reactive material 402. In regions where the reactive material 402 was already deposited during the first deposition process (block 106), the thickness of the reactive material 402 may be slightly thicker (e.g., two or more monolayers) after the second deposition process (block 108). Importantly, as shown in FIG. 7B, the area of interest 206, which remains protected by the mask 302 during the second deposition process (block 108), remains free of the reactive material 402.

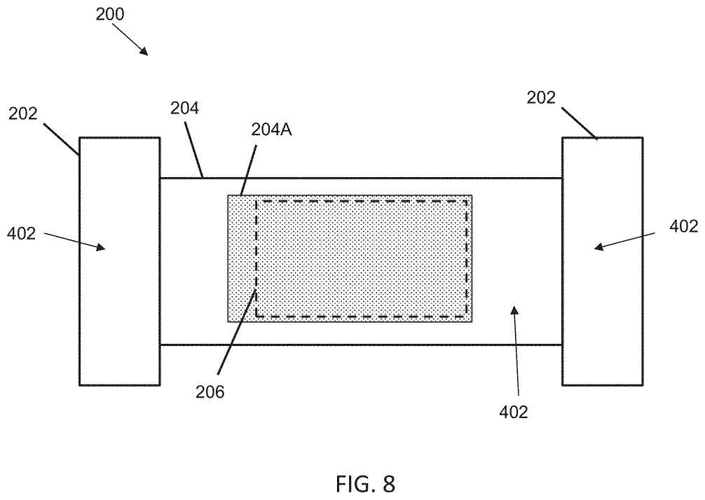

With reference to FIG. 8, illustrated therein is the substrate 204 and the clamps 202, after the second deposition of the reactive material 402 (block 108), and with the mask 302 removed. As shown, by repositioning the mask 302 and the support bar 304 and performing the second deposition, the area of interest 206 may be fully circumscribed with the reactive material 402, thereby providing a complete barrier around the area of interest 206 and more effectively blocking mobile surface molecules from reaching the area of interest 206. Once again, the mask 302 has been used to effectively protect the area of interest 206 by blocking the deposition of the reactive material 402 (e.g., Ti) within the area of interest during the second deposition (block 108). FIG. 8 also illustrates the substrate region 204A, which remains free of the reactive material 402 and which includes the area of interest 206. After the second deposition of the reactive material 402 (block 108), the freshly deposited reactive material 402 may be used to further capture mobile surface molecules (block 107), once again for example, by a reaction between the reactive material 402 and impinging mobile surface molecules that effectively traps the mobile surface molecules. In some embodiments, after the second deposition (block 108), the device, circuit, material, metrology pattern, or other feature within the area of interest 206 may proceed to be used for its intended purpose.

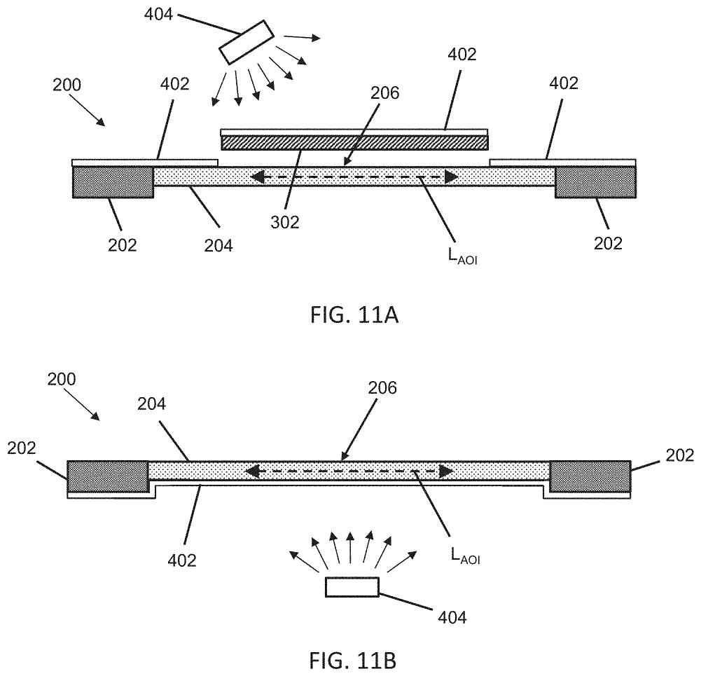

While the example of the method 100 provided for fully circumscribing the area of interest 206 with the reactive material 402 by repositioning the mask 302 and the support bar 304 and performing the second deposition (block 108 and FIGS. 6A, 6B, 7A, 7B), other methods for fully circumscribing the area of interest 206 are possible. For example, in some embodiments, the support bar 304 (which holds the mask 302 in position) may be designed to have width ‘w’ that is thin enough to allow the penumbral blur from the reactive material source 404 to reach under the support bar 304, and thereby deposit the reactive material 402 under the support bar 304 during the first deposition (block 106). For example, assuming that the substrate 204, the mask 302, and the reactive material source 404 lie in parallel planes to each other, then the width ‘w’ of the support bar 304 should be less than about w1*d/Dₘ, where ‘w1’ is the effective width of the reactive material source 404, Dm is the distance between the mask 302 and the reactive material source 404, and d is the distance between the mask 302 and the substrate 204. Stated another way, the width ‘w’ of the support bar 304 should be thin enough that there is a direct line of sight from all points of the substrate 204 underneath the support bar 304 (having a width ‘w’) to the reactive material source 404 (having an effective width ‘w1’). In this case, there may be a reduction in the amount of reactive material 402 (e.g., Ti) deposited under the support bar 304, but as long as there is at least one monolayer of the reactive material 402 deposited under the support bar 304, then the second deposition (block 108) would not be necessary. In another example, the reactive material source 404 may be positioned at a first angle (e.g., normal to a surface of the substrate 204, as shown in FIG. 4B) for the first deposition (block 106) and positioned at a second angle (e.g., between 0° and 90° with respect to the surface of the substrate 204, as shown in FIG. 11A) for the second deposition (block 108), without requiring the mask 302 and the support bar 304 to be repositioned (e.g., moved the distance ‘d1’) for the second deposition (block 108). In general, both the first deposition (block 106) and the second deposition (108) may be performed with the reactive material source 404 positioned at any angle with respect to the substrate surface, where the first deposition is performed at a different angle than the second deposition, and where the area of interest 206 remains free of the reactive material 402. In some alternative embodiments, the reactive material source 404 may be positioned below the substrate 204 (e.g., on the opposite side of the substrate 204 as illustrated in FIG. 4B, as shown in FIG. 11B), and directed toward a back surface of the substrate, so that the back surface of the substrate, or the substrate holder, is coated with the reactive material 402, while the area of interest 206, on a front surface of the substrate 204, remains free of the reactive material 402. In such an example, the substrate 204 or substrate holder may act as a mask, without the need for a separate shadow mask (e.g., such as the mask 302), shielding the area of interest 206 from a direct flux of the reactive material 402, as the area of interest 206 is not in a line of sight of the reactive material source 404.

As noted above, the reactive material 402 may include Ti, which is known to be a very reactive material. As a result, titanium sublimation pumps (TSPs) are routinely used as UHV pumps to further pump down the pressure of a vacuum chamber. By way of example, TSPs rely on other types of vacuum pumps to achieve UHV levels of pressure within a vacuum chamber, after which a layer of Ti metal is deposited on interior surfaces of the vacuum chamber through a sublimation process. As described above with reference to the reactive material source 404, the TSP sublimation process may be similarly accomplished by passing an electrical current through a Ti filament (e.g., a Ti wire or rod) to raise the temperature of the Ti filament to a high enough value where the Ti begins to sublimate from the filament and deposits on the interior surfaces of the vacuum chamber. Generally, the TSP is run only for a short time such that approximately a monolayer of Ti is deposited, as only the Ti surface atoms will contribute to the further pumping down of the pressure of the vacuum chamber. The pumping effect of the TSP is driven by a reaction between the fresh Ti coating (e.g., freshly sublimated coating) and impinging gas molecules within the chamber, where the Ti coating traps the gas molecules and removes them from the vacuum environment. The adsorbed gas molecules themselves are not reactive, and therefore the fresh Ti coating is only reactive until the entire surface of the Ti coating is saturated with gas molecules. Therefore, TSPs pump at their highest rates immediately after the Ti sublimation event and their pumping speed constantly diminishes and will be proportional to the area of the reactive Ti surface that has yet to be rendered unreactive by the capture of gas molecules. TSPs are generally used just before another process is run in a UHV chamber, for example, where the highest possible vacuum is desired. In some cases, the TSPs may be run periodically (e.g., such as every few hours) to refresh the Ti surface and maintain the overall pumping speed of the TSP, and thus to maintain a desired vacuum level of the vacuum chamber.

To be sure, using a Ti layer to capture mobile surface molecules on a substrate surface, as in embodiments of the present disclosure, may have a different dynamic than that observed in TSPs. For example, while the various embodiments discussed herein describe that the Ti is deposited (e.g., as shown in FIGS. 4A, 4B, 7A, and 7B) in order to capture mobile surface molecules, the deposited Ti will also be trapping gas molecules. As such, and in accordance with some embodiments, the greatest reduction of mobile surface molecules may be expected to occur when the flux of mobile surface molecules is significantly greater than the flux of gas molecules impinging on the surface of the substrate 204. Generally, the flux of mobile surface molecules is orders of magnitude greater than the flux of molecules arriving at the surface of the substrate 204 from the gas phase. However, the ratio of the flux of mobile surface molecules compared to the flux of molecules arriving from the gas phase can be quite variable depending on the source and/or type of the mobile surface molecules. Assuming a significantly greater flux of mobile surface molecules as compared to the flux of gas molecules, and in some embodiments, the mobile surface molecules may first begin to coat the edges of the Ti layer as they are captured by the exposed Ti.

In a first case, if the mobile surface molecules that are trapped by the edge of the reactive Ti surface are also mobile on Ti surfaces already including trapped mobile surface molecules, then the mobile surface molecules may travel over the trapped molecules until they reach a reactive fresh Ti surface and are then themselves trapped. In such an example, the effective reduction of the mobile surface molecules is proportional to the periphery of the reactive material (ignoring the reduction of the available reactive area due to gas phase pumping). This first case is consistent with empirical observations, which show that larger reactive areas of Ti, having larger peripheral areas, are more effective at reducing the mobile surface molecules.

In a second case, if the mobile surface molecules that are trapped by the edge of the reactive Ti surface are not mobile on Ti surfaces already including trapped molecules, and the mobile surface molecules have a large sticking coefficient on the layer of trapped molecules, then the effectiveness of the applied reactive layer should be relatively constant over time. This second case is not consistent with empirical observations, which show that the effectiveness of the deposited Ti is not indefinite. However, in either the first or second cases just described, the effectiveness of the deposited reactive material 402 on a portion of the substrate 204 can be achieved.

In a third case, if the mobile surface molecules that are trapped by the edge of the reactive Ti surface are not mobile on Ti surfaces already including trapped molecules, but also are not captured at a high rate, then the mobile surface molecules may essentially reflect off of the layer of trapped molecules at the edges of the reactive Ti material. In this case the reactive Ti material would have a short-lived effect. This third case is also not consistent with empirical observations, which show that the application of a layer of Ti on a portion of the substrate does indeed have a long-lasting effect.

In some embodiments, the period of time within which the Ti layer (or other reactive coating) remained effective could be extended, for example, by using a “metal black” deposition method. In some examples, the metal black deposition method may be accomplished by evaporation, sublimation, or another physical vapor deposition method that is carried out in a relatively low vacuum (˜1 Torr), and where the predominant background gas is an inert gas (e.g., such as argon) but the partial pressures of reactive gases, such as water, oxygen, etc. are very low. Under appropriate deposition conditions, evaporated or sublimed metal atoms may be deflected by the inert gas atoms and form into small blobs or globules that when deposited on a substrate surface create a very low-density, high-surface area coating, which may be formed by the blobs or globules sticking to each other and forming filaments. Such metal black coatings are typically formed using noble metals so they will not oxidize and are used to make surfaces having extremely low reflectivity, hence the name, “metal black”. In some embodiments that employ a metal black layer or coating, the metal black layer may be deposited during one or both of the first deposition process (block 106) and the second deposition process (block 108) of the method 100, described above.

If prepared in-situ, metal black layers or coatings formed with reactive metals such as Ti could be used to provide reactive surfaces having much larger surface areas, and therefore would remain effective in stopping mobile surface molecules for much longer than a smooth, monolayer of Ti. In order to achieve complete coverage of a substrate surface however, it may be appropriate to first deposit a smooth, monolayer of Ti (or other reactive material) prior to the formation of the metal black layer. In the case of a reactive metal black layer, the deposition could take place in a separate vacuum chamber coupled to a UHV chamber but separated by a gate valve, where the separate vacuum chamber could be backfilled with pure Ar or another inert gas. After deposition of the metal black layer, the Ar could be pumped away by a turbo/roughing pump combination, while any minor amount of Ar that got into the UHV chamber could be pumped by ion pumps, and any residual Ar that remained in the UHV chamber would cause substantially no trouble since it is inert. In some embodiments, after formation of the smooth, monolayer of Ti (or other reactive material), a non-reactive metal black layer may be formed (e.g., in the separate vacuum chamber coupled to the UHV chamber) over the monolayer of Ti (or other reactive material) using a noble metal. After formation of the non-reactive metal black layer, the substrate may be transferred in-situ to the UHV chamber where the reactive material 402 may then be deposited onto the non-reactive metal black layer using a mask and depositing the reactive material 402 at different angles, as discussed above, to try to coat a significant portion of the non-reactive metal black layer with the reactive material 402 while the area of interest remains free of the reactive material 402.

With reference now to FIGS. 9A and 9B, an exemplary application of the present disclosure, involving an STM HDL process, is shown. As previously discussed, in an HDL process, an STM is used to perform a lithography process via electron induced desorption of H atoms from a Si (100) 2X1 H-passivated surface. As shown in the exemplary STM image 900 of FIG. 9A, an HDL process was performed to pattern square features 902, 904 on a front surface of a substrate. The exemplary STM image 900 was captured immediately after patterning, and the square features 902, 904 which define clean areas of Si (e.g., H-depassivated regions) were found to be contaminated by large blobs or globules within the depassivated area (i.e., within the square features 902, 904). It is also noted that such large blobs or globules were not visible on the substrate surface prior to patterning of the square features 902, 904. It is assumed that the large blobs or globules were formed by mobile surface molecules which had diffused into the clean areas (square features 902, 904) and chemisorbed thereon, or had been cracked by the electron beam of the STM and made reactive with the clean areas (square features 902, 904) and chemisorbed thereon. After patterning the square features 902, 904, and in the present example, Ti was then deposited onto a back surface of the substrate, while the STM tip was still within fine piezo range of the front surface of the substrate. As a result, a dramatic reduction in accumulated surface contamination from depositing Ti on the back surface of the substrate is observed. For example, FIG. 9B shows an exemplary STM image 906 where an HDL process was performed to pattern square features 908, 910 on the front surface of the substrate (on the same substrate as FIG. 9A, and without any re-preparation of the surface) after deposition of the Ti on the back surface of the substrate. It is evident that the square features 908, 910 show a complete absence of the large blobs or globules observed prior to Ti deposition, presumably because the mobile surface molecules have diffused across the substrate surface to the reactive Ti surface and have become immobilized thereon. In some examples, the clean areas (square features 908, 910) remain free of contamination for several days, demonstrating the lifetime of the effect of the deposited Ti.

In another exemplary application, FIGS. 10A-10D illustrate XPS spectra before and after Ti deposition (evaporation) in UHV on a molybdenum disulfide (MoS₂) surface. Referring first to FIG. 10A, a prominent carbon peak, which is the ubiquitous carbon peak discussed above, is measured before Ti deposition (1002). After Ti deposition (1004), the carbon signal has been significantly reduced (e.g., by about 21%). Forty-eight hours after Ti deposition (1006), the carbon signal slightly increases while remaining significantly lower than before Ti deposition (1002). FIG. 10B shows XPS spectra for oxygen before (1008), after (1010), and 48 hours after Ti deposition (1012). The oxygen signal increases both after Ti deposition (1010) and 48 hours later (1012). In particular, it is noted that the increase in the carbon signal 48 hours after Ti deposition (1006) is much lower than the increase in the oxygen signal 48 hours after Ti deposition (1012), which supports the premise that carbon arrives via mobile surface hydrocarbon molecules while the oxygen arrives from the gas phase. FIG. 10C shows XPS spectra for Ti before (1014), after (1016), and 48 hours after Ti deposition (1018). Forty eight hours after Ti deposition (1018) the Ti signal decreased, while the oxygen signal increased 48 hours after Ti deposition (1012), which is likely due to gettering (by the Ti) of oxygen within the vacuum chamber (e.g., CO, CO₂, or other residual gases). In some cases, the Ti signal may also decrease due to diffusion into and/or reaction with the underlying bulk substrate material. FIG. 10D shows XPS spectra for molybdenum before (1020), after (1022), and 48 hours after Ti deposition (1024). As shown, an elemental molybdenum peak appears due to the Ti reacting with the MoS₂.

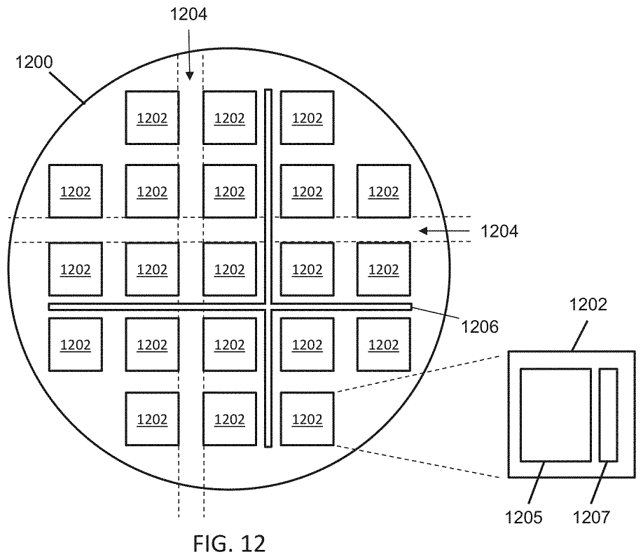

Referring now to FIG. 12, a further exemplary application of the present disclosure is illustrated. FIG. 12 shows a semiconductor wafer 1200 including a plurality of die 1202. In various examples, each of the plurality of die 1202 may include an integrated circuit, or portion thereof, that may comprise static random access memory (SRAM) and/or other logic circuits, passive components such as resistors, capacitors, and inductors, and active components such as MOSFETs, CMOS devices, FinFET devices, strained-semiconductor devices, SOI devices, partially- or fully-depleted SOI devices, bipolar transistors, high voltage transistors, high frequency transistors, memory cells, and/or or other devices or combinations thereof. By way of example, scribe lines 1204 may be defined on the semiconductor wafer 1200 in regions adjacent to and between each of the plurality of die 1202. In some embodiments, one or more of the plurality of die 1202 may include an area of interest (or an entire die 1202 itself may define the area of interest) for which protection from mobile surface molecules is desired. As a result, and in some examples, deposition of a reactive material 1206 (e.g., such as Ti) in at least portions of the scribe lines 1204 may be performed while masking one or more of the plurality of die 1202 from the deposition. In such an example, it may be impractical to use a mask such as the mask 302 discussed above with reference to the method 100. However, for one skilled in the art of making shadow masks, there are straight forward approaches to deal with this situation. For instance, one example method of depositing the reactive material 1206 in the scribe lines 1204 of the wafer 1200 would be to use two masks, one for each of two separate deposition processes. For example, a first mask with vertical slits aligned with vertically-oriented scribe lines 1204 may be used for a first deposition of reactive material, and a second mask with horizontal slits aligned with horizontally-oriented scribe lines 1204 may be used for a second deposition of reactive material, thus providing reactive material in all scribe lines 1204. As a result of the deposition of the reactive material 1206, the one or more plurality of die 1202 are protected from mobile surface contamination that could detrimentally affect the circuits and/or devices disposed therein. FIG. 12 also provides a zoomed-in view of one of the plurality of die 1202, which includes both an area of interest 1205 and a reactive material region 1207 within which the reactive material 1206 may be deposited. In such an example, a portion of the die 1202 including the area of interest 1205 may be masked by a portion of the shadow mask(s) while the reactive material 1206 is deposited in the reactive material region 1207 through a slit in one of the shadow masks. In some cases, it may be difficult to deposit the reactive material on the backside of the substrate or completely circumscribing the area of interest. In these cases, deposition of the reactive material anywhere on the substrate may still provide some benefit by effectively reducing the number of mobile surface molecules.

It will be understood that the examples applications given above, as well as the examples discussed with reference to the method 100, are merely exemplary and are not meant be limiting in any way. Moreover, those of skill in the art in possession of this disclosure will recognize that various additional embodiments may be implemented in accordance with the methods described herein, while remaining within the scope of the present disclosure.

The various embodiments described herein offer several advantages over the existing art. It will be understood that not all advantages have been necessarily discussed herein, no particular advantage is required for all embodiments, and other embodiments may offer different advantages. For example, embodiments discussed herein include methods for reducing the amount of mobile surface molecules present on surfaces in UHV systems or within other controlled environments. In various embodiments, this may be accomplished by depositing a layer of a reactive material (e.g., such as Ti) in-situ onto a substrate. In various examples, the process is carried out in a UHV vacuum chamber, for example, so that the reactive material will not be rendered unreactive in a very short period of time. In some examples, a substrate may include an area of interest defining a region targeted for protection from and/or reduction in mobile surface molecules. In some embodiments, the reactive material deposited in-situ may be deposited on a portion of the substrate surface outside, but in some cases adjacent to, the area of interest. That is, the area of interest may remain protected or free from the reactive material so as not to interfere with the device, circuit, material, metrology pattern, or other feature within the area of interest. By depositing the reactive material on a substrate surface, in accordance to the embodiments described herein, mobile surface molecules may be captured by the reactive material and thereby prevented from contaminating the area of interest. Thus, embodiments of the present disclosure provide a reliable method for reducing the amount of mobile surface molecules present on a substrate surface (e.g., in a UHV environment) to protect areas of interest from contamination by the mobile surface molecules.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a substrate including an area of interest, wherein the substrate is disposed within a controlled environment;
positioning a mask over the area of interest and between the substrate and a reactive material source within the controlled environment;
performing a first deposition of a reactive material from the reactive material source onto a first portion of the substrate, wherein the mask blocks deposition of the reactive material within the area of interest such that the area of interest remains substantially free of the reactive material; and
capturing mobile surface molecules using the reactive material deposited onto the first portion of the substrate.

2. The method of claim 1, further comprising:
repositioning the mask over the area of interest and between the substrate and the reactive material source; and
performing a second deposition of the reactive material from the reactive material source onto a second portion of the substrate, wherein the mask blocks deposition of the reactive material within the area of interest such that the area of interest remains substantially free of the reactive material;
wherein as a result of the performing the second deposition, the area of interest is circumscribed by the reactive material.

3. The method of claim 1, wherein the performing the first deposition is performed with the reactive material source disposed at a first angle with respect to the substrate, and wherein the method further comprises:
performing a second deposition of the reactive material from the reactive material source onto a second portion of the substrate, wherein the reactive material source is disposed at a second angle with respect to the substrate, and wherein the mask blocks deposition of the reactive material within the area of interest such that the area of interest remains substantially free of the reactive material;
wherein as a result of the performing the second deposition, the area of interest is circumscribed by the reactive material.

4. The method of claim 1, wherein the mask is held in position by a support bar having a width configured to allow a penumbral blur from the reactive material source to reach under the support bar such that the area of interest is circumscribed by the reactive material after the first deposition.

5. The method of claim 1, wherein the reactive material includes titanium (Ti).

6. The method of claim 1, wherein the controlled environment includes an ultra-high vacuum (UHV) environment.

7. The method of claim 1, wherein the capturing the mobile surface molecules prevents the mobile surface molecules from contaminating the area of interest.

8. The method of claim 1, wherein the first deposition of the reactive material from the reactive material source is performed by sublimation, physical vapor deposition, or electron beam evaporation of the reactive material.

9. The method of claim 1, wherein a first flux of mobile surface molecules is greater than a second flux of gas molecules impinging on a surface of the substrate.

10. The method of claim 1, wherein the first deposition of the reactive material from the reactive material source includes deposition of a metal black layer.

11. The method of claim 1, wherein the first deposition of the reactive material from the reactive material source includes sequential deposition of a first reactive material and a second reactive material, wherein the first reactive material includes titanium (Ti), and wherein the second reactive material includes a metal black layer.

12. The method of claim 1, wherein the reactive material deposited onto the first portion of the substrate has a thickness of about one monolayer.

13. A method, comprising:
providing a substrate including an area of interest, wherein the substrate is disposed within an ultra-high vacuum (UHV) environment;
positioning a mask in a first position over the area of interest, wherein the mask is held in the first position by a support bar;
performing a first deposition of a reactive material from a reactive material source onto a first substrate region, wherein the mask, while in the first position, blocks deposition of the reactive material within the area of interest, and wherein the support bar blocks deposition of the reactive material within a second substrate region;
positioning the mask in a second position over the area of interest, wherein the mask is held in the second position by the support bar, and wherein the mask, while in the second position, exposes the second substrate region;
performing a second deposition of the reactive material from the reactive material source onto the second substrate region to circumscribe the area of interest with the reactive material; and
capturing mobile surface molecules using the reactive material deposited onto the first substrate region and the second substrate region.

14. The method of claim 13, wherein the capturing the mobile surface molecules prevents the mobile surface molecules from contaminating the area of interest.

15. The method of claim 13, wherein the reactive material includes titanium (Ti).

16. The method of claim 13, wherein at least one of the first deposition and the second deposition includes deposition of a metal black layer.

17. The method of claim 13, wherein at least one of the first deposition and the second deposition includes sequential deposition of a first reactive material and a second reactive material, wherein the first reactive material includes titanium (Ti), and wherein the second reactive material includes a metal black layer.

18. A method, comprising:
providing a substrate including an area of interest disposed on a front surface of the substrate, wherein the substrate is disposed within a controlled environment;
performing a deposition of a reactive material from a reactive material source onto a portion of the substrate, wherein the area of interest remains substantially free of the reactive material after deposition of the reactive material onto the portion of the substrate; and
capturing mobile surface molecules using the reactive material deposited onto the portion of the substrate.

19. The method of claim 18, wherein the reactive material source is positioned below the substrate and directed toward a back surface of the substrate opposite the front surface, wherein the portion of the substrate includes the back surface of the substrate, and wherein the substrate blocks the deposition of the reactive material within the area of interest on the front surface.

20. The method of claim 18, wherein the reactive material source is positioned above the substrate and directed toward the front surface of the substrate, wherein the portion of the substrate includes a region on the front surface of the substrate, wherein a mask is positioned over the area of interest and between the substrate and the reactive material source, and wherein the mask blocks deposition of the reactive material within the area of interest.
